(19) United States
(12) Patent Application Publication
(10) Pub. No.: US 2012/0112783 A1
(43) Pub. Date: May 10, 2012

(54) TEST APPARATUS

(75) Inventors: Masahiro Ishida, Tokyo (JP); Daisuke Watanabe, Tokyo (JP); Masayuki Kawabata, Tokyo (JP); Toshiyuki Okayasu, Tokyo (JP)

(73) Assignee: ADVANTEST CORPORATION, Tokyo (JP)

(21) Appl. No.: 13/287,950

(22) Filed: Nov. 2, 2011

(30) Foreign Application Priority Data
Nov. 4, 2010 (JP) 2010-247788

(51) Int. Cl. G01R 31/26

(52) U.S. Cl. 324/762.02

(57) ABSTRACT

A test apparatus tests a DUT formed on a wafer. A power supply compensation circuit includes source and a sink switches each controlled according to a control signal. When the source or sink switch is turned on, a compensation pulse current is generated, and the compensation pulse current is injected into a power supply terminal of the DUT via a path that differs from that of a main power supply, or is drawn from the power supply current that flows from the main power supply to the DUT via a path that differs from that of the power supply terminal of the DUT. Of components forming the power supply compensation circuit, including the source and sink switches, a part is formed on the wafer. Pads are formed on the wafer in order to apply a signal to such a part of the power supply compensation circuit formed on the wafer.

### BACKGROUND OF THE INVENTION

1. Field of the Invention

The present invention relates to a technique for stabilizing a power supply.

2. Description of the Related Art

In a testing operation for a semiconductor integrated circuit that employs CMOS (Complementary Metal Oxide Semiconductor) technology (which will be referred to as the “DUT” hereafter) such as a CPU (Central Processing Unit), DSP (Digital Signal Processor), memory, or the like, electric current flows in a flip-flop or a latch included in the DUT while it operates receiving the supply of a clock. When the clock is stopped, the circuit enters a static state in which the amount of current decreases. Accordingly, the sum total of the operating current (load current) of the DUT changes over time depending on the content of the test operation, and so forth.

A power supply circuit configured to supply electric power to such a DUT has a configuration employing a regulator, for example. Ideally, such a power supply circuit is capable of supplying constant electric power regardless of the load current. However, in actuality, such a power supply circuit has an output impedance that is not negligible. Furthermore, between the power supply circuit and the DUT, there is an impedance component that is not negligible. Accordingly, the power supply voltage fluctuates due to fluctuation in the load.

Fluctuation in the power supply voltage seriously affects the test margin for the DUT. Furthermore, such fluctuation in the power supply voltage affects the operations of other circuit blocks included in the test apparatus, such as a pattern generator configured to generate a pattern to be supplied to the DUT, a timing generator configured to control the pattern transition timing, etc., leading to deterioration in the test accuracy.

With such a technique described in Patent document 2, such an arrangement includes a compensation circuit including a switch configured to switch on an off according to the output of a driver, in addition to a main power supply configured to supply a power supply voltage to a device under test. With such an arrangement, a compensation control pattern to be applied to a switch element is defined according to the test pattern so as to cancel out fluctuation in the power supply voltage that would occur according to the test pattern to be supplied to the device under test. In an actual test operation, such an arrangement supplies a test pattern to such a device under test while switching the switch included in the compensation circuit according to the control pattern, thereby maintaining the power supply voltage at a constant level.

### RELATED ART DOCUMENTS

### Patent Documents

### [Patent Document 1]

Japanese Patent Application Laid Open No. 2007-205813

[Patent document 2]

International Publication WO 10/029709A1 pamphlet

The present inventors have investigated such a test apparatus described in Patent document 2, and have come to recognize the following problems.

With such a test operation for a semiconductor device, there are two kinds of test operations, i.e., a test operation for a device under test which has been packaged after the assembling process (final test), and a test operation for a device under test in the form of a chip on a wafer before the assembling process (probe test). With such an arrangement, the probe test is performed in a difficult power supply environment, as compared with that in which the final test is performed. Thus, the compensation technique for the power supply voltage is critical not only in the final test, but also in the probe test.

With such an arrangement, the probe test is performed in a state in which probes are pressed in contact with pads arranged on a device under test on a wafer. Accordingly, the correction using a compensation current is subject to effects of the resistance component and the inductance component of each probe itself, or the contact resistance that occurs between each probe and the chip. This leads to difficulty in maintaining the power supply voltage at a constant level, or leads to difficulty in emulating a user-desired power supply environment.

### SUMMARY OF THE INVENTION

The present invention has been made in view of such a situation. Accordingly, it is an exemplary purpose of the present invention to provide a test apparatus which is capable of emulating an ideal power supply environment, or a desired power supply environment.

An embodiment of the present invention relates to a test apparatus configured to test a device under test formed on a wafer. The test apparatus comprises: a main power supply configured to supply electric power to a power supply terminal of the device under test; a power supply compensation circuit comprising a switch element configured to be controlled according to a control signal, and configured to generate a compensation pulse current when the switch element is turned on, and to inject the compensation pulse current thus generated into the power supply terminal via a path that differs from that of the main power supply, or to draw the compensation pulse current from the power supply current that flows from the main power supply to the device under test via a path that differs from that of the device under test; multiple drivers, one of which is assigned to the switch element, and of which at least one other is assigned to at least one of the input/output terminals of the device under test; multiple interface circuits provided to the respective drivers, each configured to shape an input pattern signal, and to output the pattern signal thus shaped to the corresponding driver; and a pattern generator configured to output a test pattern which specifies a test signal to be output from the driver assigned to the input/output terminal of the device under test to the interface circuit that corresponds to the driver, and to output, to the interface circuit that corresponds to the driver assigned to the switch element, a control pattern determined according to the test pattern. At least one part of the power supply compensation circuit, including the switch element, is formed on the wafer. A compensation pad is arranged via which a signal is applied to the at least one part of the power supply compensation circuit formed on the wafer.

With such an embodiment, a part of the power supply compensation circuit is formed on a wafer. Thus, at the time of the probe test, such an arrangement allows the compensation pulse current to be generated on the wafer, i.e., in the vicinity of the device under test. As a result, such an arrangement is capable of providing power supply compensation while suppressing the effects of the impedance of the probes.

Furthermore, variations that occur in the elements of the power supply compensation circuit formed on the wafer are similar to those that occur in the elements of the device under test. Thus, such an arrangement is able to provide a suitable compensation current that follows variations in the device under test.

Also, at least one part of the power supply compensation circuit formed on the wafer and the compensation pad may be formed within a chip in which the device under test is configured.

Also, the compensation pad may be formed with a size which allows a probe to be in contact with the compensation pad, and which is smaller than the size of a function pad which is connected to an external connection terminal when the device under test is packaged.

In a case in which the power supply compensation circuit formed within the chip is only required at the time of the probe test, the compensation pads may be formed with a sufficiently small size, thereby suppressing an increase in the chip size.

Also, the compensation pad may be connected to an external connection terminal when the device under test is packaged. Such an arrangement also provides power supply compensation using the power supply compensation circuit formed within the chip, even in testing after the assembling process.

Also, at least one part of the power supply compensation circuit formed on the wafer and the compensation pad may be formed in a dicing area external to the chip in which the device under test is formed.

In a case in which the power supply compensation circuit formed on the wafer is only required for the probe test, it may be formed in the dicing area. Such an arrangement suppresses an increase in the chip area.

Also, at least one part of the power supply compensation circuit formed on the wafer and the compensation pad may be formed in a power compensation circuit chip that is separate from the chip in which the device under test is formed.

Also, at least one part of the power supply compensation circuit formed on the wafer and the compensation pad may be shared by multiple devices under test. In a case in which such power supply compensation circuit chips are arranged on a wafer, the number of product chips produced from a wafer is reduced due to the area of such power supply compensation circuit chips. With such an arrangement in which such a power supply compensation circuit chip is shared by multiple chips, such an arrangement suppresses a reduction in the number of product chips.

Also, of wiring lines respectively connected to the at least one part of the power supply compensation circuit formed on the wafer and the compensation pad, a wiring line that straddles a boundary of the chip may be formed as an aluminum wiring line. In a case in which the wiring line is arranged across the dicing line, the cross-sectional surface of the wiring line is exposed to air or moisture after the dicing. In some cases, this leads to deterioration in long-term reliability. In order to solve such a problem, such a wiring line is configured as a first layer aluminum wiring line, thereby suppressing deterioration in reliability.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram which shows a configuration of a test apparatus according to an embodiment;

FIG. 2 is a flowchart which shows an example of a method for calculating a control pattern;

FIG. 3 is a waveform diagram which shows an example of an operating current I_{OP}, a power supply current I_{DD}, a source compensation current I_{CMP}, and a source pulse current I_{SRC};

FIGS. 4A and 4B are circuit diagrams each showing an example configuration of a power supply compensation circuit;

FIGS. 5A through 5C are circuit diagrams each showing a different example configuration of a power supply compensation circuit;

FIG. 6 is a first example in which a part of the power supply compensation circuit shown in FIG. 4A is formed on a wafer;

FIG. 7 is a second example in which a part of the power supply compensation circuit shown in FIG. 4A is formed on a wafer; and

FIG. 8 is a third example in which a part of the power supply compensation circuit shown in FIG. 4A is formed on a wafer.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

In the present specification, the state represented by the phrase “the member A is connected to the member B” includes a state in which the member A is indirectly connected to the member B via another member that does not substantially affect the electric connection therebetween, or that does not damage the functions or effects of the connection therebetween, in addition to a state in which the member A is physically and directly connected to the member B. Similarly, the state represented by the phrase “the member C is provided between the member A and the member B” includes a state in which the member A is indirectly connected to the member C, or the member B is indirectly connected to the member C via another member that does not substantially affect the electric connection therebetween, or that does not damage the functions or effects of the connection therebetween, in addition to a state in which the member A is directly connected to the member C, or the member B is directly connected to the member C.

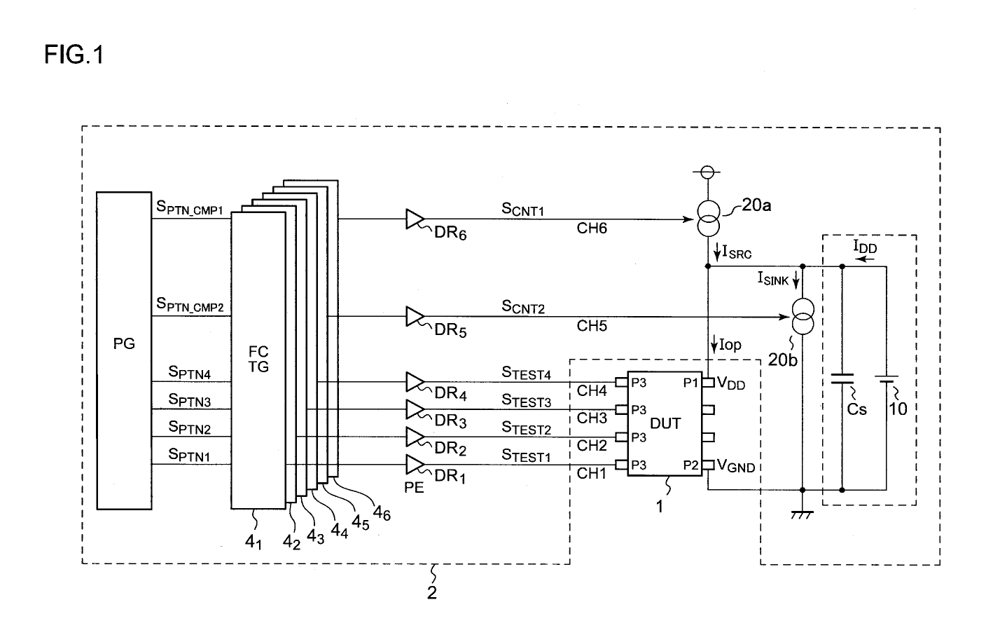

FIG. 1 is a circuit diagram which shows a configuration of a test apparatus 2 according to an embodiment. FIG. 1 shows a semiconductor device (which will be referred to as “DUT” hereafter) 1, in addition to the test apparatus 2.

The DUT 1 includes multiple pins. At least one of the multiple pins is a power supply terminal P1 configured to receive a power supply voltage V_{DD}, and at least one other pin is configured as a ground terminal P2. Multiple input/output (I/O) pins P3 are each configured to receive data from outside the circuit or to output data to outside the circuit. In the test operation, the multiple input/output terminals P3 receive a test signal (test pattern) S_{TEST} output from the test apparatus 2, or output data that corresponds to the test signal S_{TEST} to the test apparatus 2. FIG. 1 shows only a part of the configuration of the test apparatus 2, which is configured to supply a test signal to the DUT 1. That is to say, another configuration thereof configured to evaluate a signal received from the DUT 1 is not shown.

The test apparatus 2 includes a main power supply 10, a pattern generator PG, multiple timing generators TG, multiple waveform shapers FC, multiple drivers DR, and a power supply compensation circuit 20.

The test apparatus 2 includes multiple channels, e.g., n channels CH1 through CHn, several channels (CH1 through CH4) of which are respectively assigned to the multiple I/O terminals P3 of the DUT 1. FIG. 1 shows an arrangement in which n=6. However, in practical use, the number of channels of the test apparatus 2 is on the order of several hundred to several thousand.

The main power supply 10 generates the power supply voltage V_{DD} to be supplied to the power supply terminal P1 of the DUT 1. For example, the main power supply 10 is configured as a linear regulator, a switching regulator, or the like, and performs feedback control such that the power supply voltage V_{DD} to be supplied to the power supply terminal P1 matches a target value. The capacitor Cs is provided in order to smooth the power supply voltage V_{DD}. The main power supply 10 is configured to generate a power supply voltage to be supplied to the DUT 1. In addition, the main power supply 10 is further configured to generate a power supply voltage to be supplied to the other circuit blocks included in the test apparatus 2. The output current flowing from the main power supply 10 to the power supply terminal P1 of the DUT 1 will be referred to as the “power supply current I_{DD}”.

The main power supply 10 is configured as a voltage/current source having a limited response speed. Accordingly, in some cases, the main power supply 10 cannot follow a sudden change in the load current, i.e., the operating current I_{OP} of the DUT 1. For example, when the operating current I_{OP} changes in a stepwise manner, overshoot or undershoot occurs in the power supply voltage V_{DD}, following which, in some cases, ringing occurs in the power supply voltage V_{DD}. Such fluctuation in the power supply voltage V_{DD} leads to difficulty in testing the DUT 1 with high precision. This is why, when an error is detected in the operation of the DUT 1, such an arrangement cannot judge whether such an error is due a manufacturing fault in the DUT 1 or due to the fluctuation in the power supply voltage V_{DD}.

The power supply compensation circuit 20 is provided in order to compensate for the response speed of the main power supply 10. The designer of the DUT 1 can estimate the change over time in the operating rate of an internal circuit of the DUT 1 and so forth when a known test signal S_{TEST} (test pattern S_{PTN}) is supplied to the DUT 1. Accordingly, the designer can predict the waveform of the operating current I_{OP} of the DUT 1 over time with high precision. Examples of such a prediction method include a calculation method using computer simulation, or an actual measurement method in which a device having the same configuration as that of the DUT 1 is measured. Such a prediction method is not restricted in particular.

Furthermore, in a case in which the response speed of the main power supply 10 (feedback gain, feedback band width) is known, the designer can also estimate the power supply current I_{DD} generated by the main power supply 10 according to the estimated operating current I_{OP}. In this case, by compensating for the difference between the estimated operating current I_{OP} and the estimated power supply current I_{DD} by means of the power supply compensation circuit 20, such an arrangement is capable of stabilizing the power supply voltage V_{DD}.

It should be noted that a differential relation or an integral relation holds true between the power supply voltage V_{DD}′ and the power supply current I_{DD}. Specifically, which relation of either a differential relation or an integral relation holds true is determined depending on which component is dominant with respect to the impedance of the main power supply 10 itself and the impedance of a path from the main power supply 10 up to the power supply terminal P1 among the capacitance component, inductance component, or resistance component.

The power supply compensation circuit 20 includes a source compensation circuit 20a and a sink compensation circuit 20b. The source compensation circuit 20a is configured to be switchable between an on state and an off state according to a control signal S_{CNT1}. When the source compensation circuit 20a is turned on according to the control signal S_{CNT1,} a compensation pulse current (which will also be referred to as the “source pulse current”) I_{SRC} is generated. The power supply compensation circuit 20 is configured to inject the source pulse current I_{SRC} into the power supply terminal P1 via a path that differs from that of the main power supply 10.

Similarly, the sink compensation circuit 20b is configured to be switchable between an on state and an off state according to a control signal S_{CNT2}. When the sink compensation circuit 20b is turned on according to the control signal S_{CNT2}, a compensation pulse current (which will also be referred to as the “sink pulse current”) I_{SINK} is generated. The power supply compensation circuit 20 is configured to draw, via a path that differs from that of the DUT 1, the sink pulse signal ISNK from the power supply current I_{DD} that flows to the power supply terminal P1.

The following Expressions (1) and (2) hold true between the operating current I_{OP} that flows to the power supply terminal P1 of the DUT 1 and the compensation current I_{CMP} output from the power supply compensation circuit 20, based upon the current conservation law.

I_{OP}−I_{DD}+I_{CMP} (1)

I_{CMP}=I_{SRC}−I_{SINK} (2)

That is to say, the positive component of the compensation current I_{CMP} is supplied from the source compensation circuit 20a as the source pulse current I_{SRC}. The negative component of the compensation current I_{CMP} is supplied from the sink compensation circuit 20b as the sink pulse current I_{SINK}.

Among the drivers DR₁ through DR₆, the driver DR₆ is assigned to the source compensation circuit 20a, and the driver DR₅ is assigned to the sink compensation circuit 20b. At least one of the other drivers, e.g., the drivers DR₁ . through DR₄, are respectively assigned to at least one of the I/O terminals P3 of the DUT 1. The pattern generator PG, the drivers DR₅ and DR₆, and the interface circuits 4₅ and 4₆, can be regarded as a control circuit configured to control the power supply compensation circuit 20.

A pair comprising the waveform shaper FC and the timing generator TG is collectively referred to as an “interface circuit 4”. Multiple interface circuits 4₁ through 4₆ are respectively provided for the channels CH1 through CH6, i.e., for the drivers DR₁ through DR₆. The i-th (1≦i≦6) interface circuit 4ᵢ shapes the input pattern signal S_{PTNi} such that it has a signal format that is suitable for the driver DR, and outputs the pattern signal thus shaped to the corresponding driver DRi.

The pattern generator PG generates the pattern signals S_{PTN} for the interface circuits 4₁ through 4₆ according to a test program. Specifically, with regard to the drivers DR₁ through DR₄ respectively assigned to the I/O terminals P3 of the DUT 1, the pattern generator PG outputs the test patterns S_{PTNi}, each specifying a test signal S_{TESTi} to be generated by the corresponding driver DRi, to the respective interface circuits 4ᵢ that correspond to the respective drivers DRi. Each test pattern S_{PTNi} includes data which represents the signal level for each cycle (unit interval) of the test signal S_{TESTi}, and data which indicates the timing at which the signal level transits.

Furthermore, the pattern generator PG generates compensation control patterns S_{PTN}_{_{—}}_{CMP} determined according to the required compensation current I_{CMP}. The control patterns S_{PTN}_{_{—}}_{CMP} are composed of a control pattern S_{PTN}_{_{—}}_{CMP1} which specifies the control signal S_{CNT1} to be generated by the driver DR₆ assigned to the source compensation circuit 20a, and a control pattern S_{PTN}_{_{—}}_{CMP2} which specifies the control signal S_{CNT2} to be generated by the driver DR₅ assigned to the sink compensation circuit 20b. The control patterns S_{PTN}_{_{—}}_{CMP1} and S_{PTN}_{_{—}}_{CMP2} respectively include data which specifies the on/off state of the source compensation circuit 20a for each cycle, and data which specifies the on/off state of the sink compensation circuit 20b for each cycle. Furthermore, the control patterns S_{PTN}_{_{—}}_{CMP1} and S_{PTN}_{_{—}}_{CMP2} respectively include data which specifies the timing at which the on/off state of the source compensation circuit 20a is to be switched, and data which specifies the timing at which the on/off state of the sink compensation circuit 20b is to be switched.

The pattern generator PG generates the control patterns A_{PTN}_{_{—}}_{CMP1} and S_{PTN}_{_{—}}_{CMP2} so as to allow fluctuation in the operating current of the DUT 1 to be compensated for, according to the test patterns S_{PTN1} through S_{PTN4}, i.e., according to the fluctuation in the operating current of the DUT 1. The pattern generator PG outputs these control patterns S_{PTN}_{_{—}}_{CMP1} and S_{PTN}_{_{—}}_{CMP2} to the corresponding interface circuits 4₆ and 4₅, respectively.

As described above, if the test patterns S_{PTN1} through S_{PTN4} are known, the waveform over time of the operating current I_{OP} of the DUT 1 can be estimated. Thus, the waveforms over time of the compensation current I_{CMP}, i.e., the waveforms over time of I_{SRC} and I_{SINK}, which are to be generated in order to maintain the power supply voltage V_{DD} at a constant level, can be calculated.

When the estimated operating current I_{OP} is greater than the power supply current I_{DD}, the power supply compensation circuit 20 generates a source compensation current I_{SRC} so as to compensate for a shortfall in the current. The current waveform that is required to generate such a source compensation current I_{SRC} can be predicted. Thus, the source compensation circuit 20a is controlled so as to appropriately generate the source compensation current I_{SRC}. For example, the source compensation circuit 20a may be controlled by pulse width modulation. Alternatively, pulse amplitude modulation, delta-sigma modulation, pulse density modulation, pulse frequency modulation, or the like, may be employed.

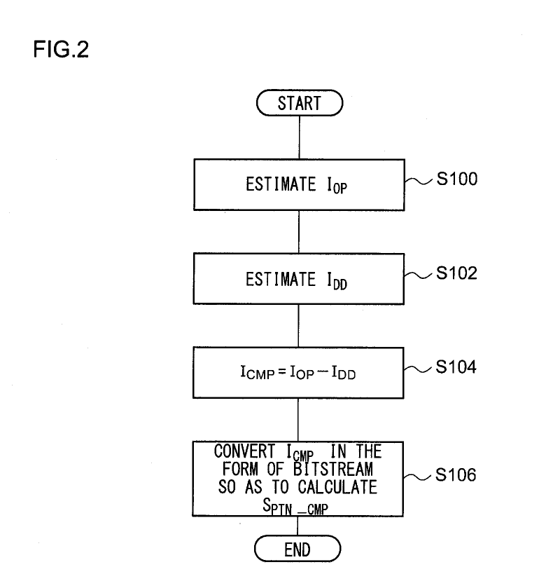

FIG. 2 is a flowchart which shows an example of a method for calculating the control pattern. The operating current I_{OP} of the DUT 1 is estimated based upon the test pattern input to the DUT 1 and the circuit information (S100). When such an event occurs in the DUT 1 in a state in which the DUT 1 is connected as a load to the main power supply 10, the power supply current I_{DD} output from the main power supply 10 is calculated (S102). In a case in which the user desires to provide an ideal power supply, the difference between the operating current I_{OP} thus estimated and the power supply current IDD thus estimated is set as the compensation current I_{CMP} to be generated by the power supply compensation circuit (S104).

Subsequently, the waveform of the compensation current I_{CMP} to be generated is subjected to delta-sigma modulation, PWM (pulse width modulation), PDM (pulse density modulation), PAM (pulse amplitude modulation), PFM (pulse frequency modulation), or the like, so as to generate a control pattern S_{PTN}_{_{—}}_{CMP} in the form of a bitstream (S106). For example, sampling of the compensation current I_{CMP} may be performed for each test cycle, and the sampled compensation current I_{CMP} may be subjected to pulse modulation.

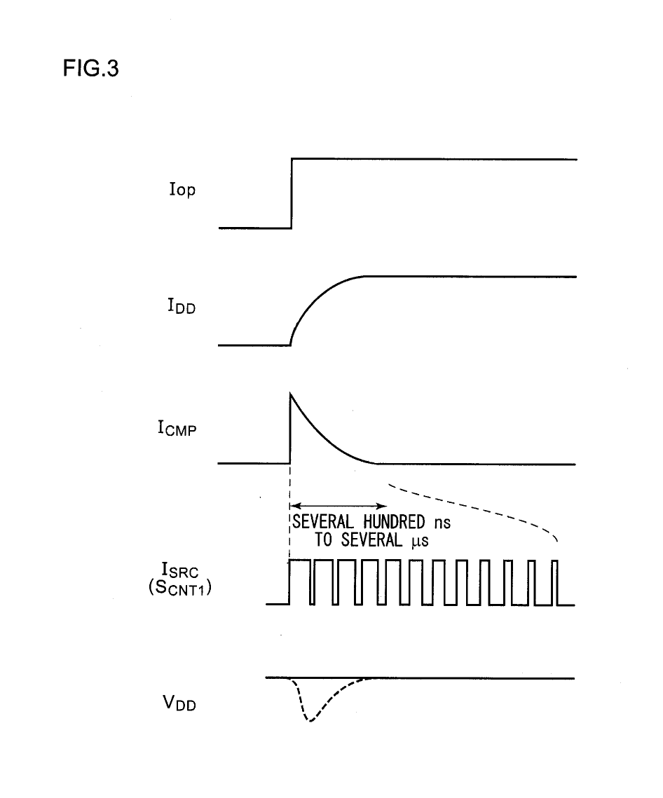

FIG. 3 is a waveform diagram which shows an example of the operating current I_{OP}, the power supply current I_{DD}, the source compensation current I_{CMP}, and the source pulse current I_{SRC}. Let us say that, when a certain test signal S_{TEST} is supplied to the DUT 1, the operating current I_{OP} of the DUT 1 rises in a stepwise manner. In response to the increase in the operating current I_{OP}, the power supply current I_{DD} is supplied from the main power supply 10. However, such a power supply current I_{DD} does not have an ideal step waveform because of the limited response speed. This leads to a shortfall in the current to be supplied to the DUT 1. As a result, if the compensation current I_{SRC} is not supplied, the power supply voltage V_{DD} falls as indicated by the broken line.

The power supply compensation circuit 20 generates the source compensation current I_{CMP} that corresponds to the difference between the operating current I_{OP} and the power supply current I_{DD}. The source compensation current I_{CMP} is provided as the source pulse current I_{SRC} generated according to the control signal S_{CNT1}. The source compensation current I_{CMP} is required to be at its maximum value immediately after the change in the operating current I_{OP}, and is required to gradually fall from its maximum value. Accordingly, the on time (duty ratio) of the source compensation circuit 20a is reduced over time using PWM (pulse width modulation), for example, thereby generating the required source compensation current I_{CMP}.

In a case in which all the channels of the test apparatus 2 operate in synchronization with a test rate, the period of the control signal S_{CNT1} matches the period (unit interval) of data to be supplied to the DUT 1, or a period obtained by multiplying or dividing the period of the data by an integer. For example, in a case in which the period of the control signal S_{CNT1} is set to 4 ns in a system in which the unit interval is 4 ns, the on period T_{ON} of each pulse included in the control signal S_{CNT1} can be adjusted in a range between 0 and 4 ns. The response speed of the main power supply 10 is on the order of several hundred ns to several μs. Thus, the waveform of the compensation current I_{CMP} can be controlled by adjusting several hundred of the pulses included in the control signal S_{CNT1}. A method for deriving the control signal S_{CNT1} required to generate the source compensation current I_{SRC} based upon the waveform thereof will be described later.

Conversely, when the operating current I_{OP} is smaller than the power supply current I_{DD}, the power supply compensation circuit 20 generates a sink pulse current I_{SINK} so as to provide the sink compensation current I_{CMP}, thereby drawing the excess current.

By providing such a power supply compensation circuit 20, such an arrangement is capable of compensating for a shortfall in the response speed of the main power supply 10, thereby maintaining the power supply voltage V_{DD} at a constant level as indicated by the solid line in FIG. 3. Furthermore, as described above, the power supply compensation circuit 20 is capable of generating a pulse current having a stabilized amplitude, thereby compensating for the power supply voltage with high precision.

The above is the overall configuration of the test apparatus 2.

Next, description will be made regarding a specific example configuration of the power supply compensation circuit 20.

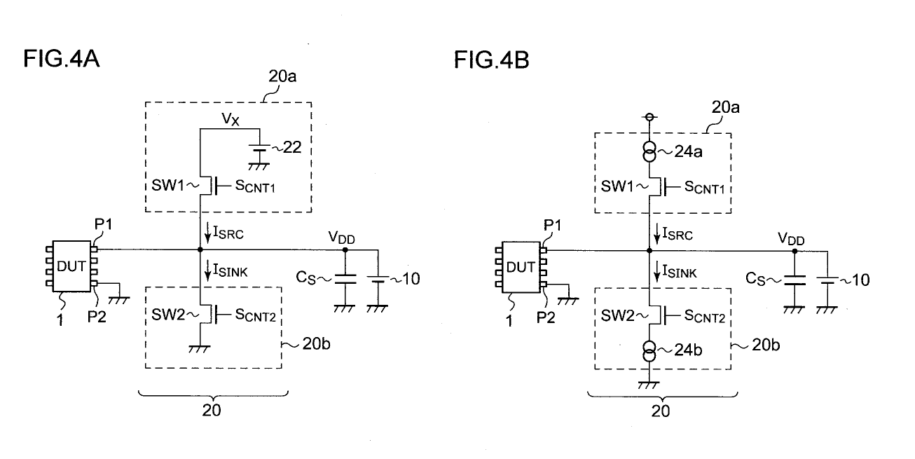

FIGS. 4A and 4B are circuit diagrams each showing an example configuration of the power supply compensation circuit 20.

Referring to FIG. 4A, the source compensation circuit 20a includes a voltage source 22 configured to generate a voltage Vx that is higher than the power supply voltage V_{DD}, and a source switch SW1. The source switch SW1 is arranged between the output terminal of the voltage source 22 and the power supply terminal P1.

If the voltage Vx and the power supply voltage V_{DD} are each maintained at a constant voltage level, when the source switch SW1 is in the on state, the amplitude of the source current I_{SRC} is represented by I_{SRC}=(Vx−V_{DD})/R_{ON1}. R_{ON1} represents the on resistance of the source switch SW1. Such arrangements shown in FIGS. 4A and 4B each have an advantage of a reduced circuit configuration of the power supply compensation circuit 20.

The sink compensation circuit 20b includes a sink switch SW2 arranged between the power supply terminal P1 and the ground terminal. When the power supply voltage V_{DD} is maintained at a constant voltage level in a state in which the sink switch SW2 is turned on, the amplitude of the sink current I_{SINK} is represented by I_{SINK}=V_{DD} /R_{ON2}. Here, R_{ON2} represents the on resistance of the sink switch SW2.

Returning to FIG. 4B, the source compensation circuit 20a includes a source current source 24a and a source switch SW1. The source current source 24a is configured to generate a reference current which determines the amplitude of the source pulse current I_{SRC}. The source switch SW1 is arranged on a path of the reference current supplied from the source current source 24a.

The sink compensation circuit 20b includes a sink switch SW2 and a sink current source 24b. The sink current source 24b is configured to generate a reference current which determines the amplitude of the sink pulse current I_{SINK}. The sink switch SW2 is arranged on a path of the reference current supplied from the sink current source 24b.

In some cases, the amplitudes of the source pulse current I_{SRC} and the sink pulse current I_{SINK} are each required to be on the order of several A. With such an arrangement, the sizes of the source switch SW1 and the sink switch SW2 shown in FIGS. 4A and 4B each become large, leading to an increase in their gate capacity. Such an increase in the gate capacity of both the source switch SW1 and the sink switch SW2 leads to each of the source switch SW1 and the sink switch SW2 having a reduced response speed. This leads to the potential to fail to generate a desired current.

Furthermore, if there are irregularities in the on resistance R_{ON1} of the source switch SW1 or in the on resistance R_{ON2} of the sink switch SW2, or if the amplitude of the control signal S_{CNT1} or the amplitude of the control signal S_{CNT2} fluctuates, the degree of the on state of each switch fluctuates. In some cases, this leads to fluctuation in the amplitude of the pulse current I_{SRC} or I_{SINK}.

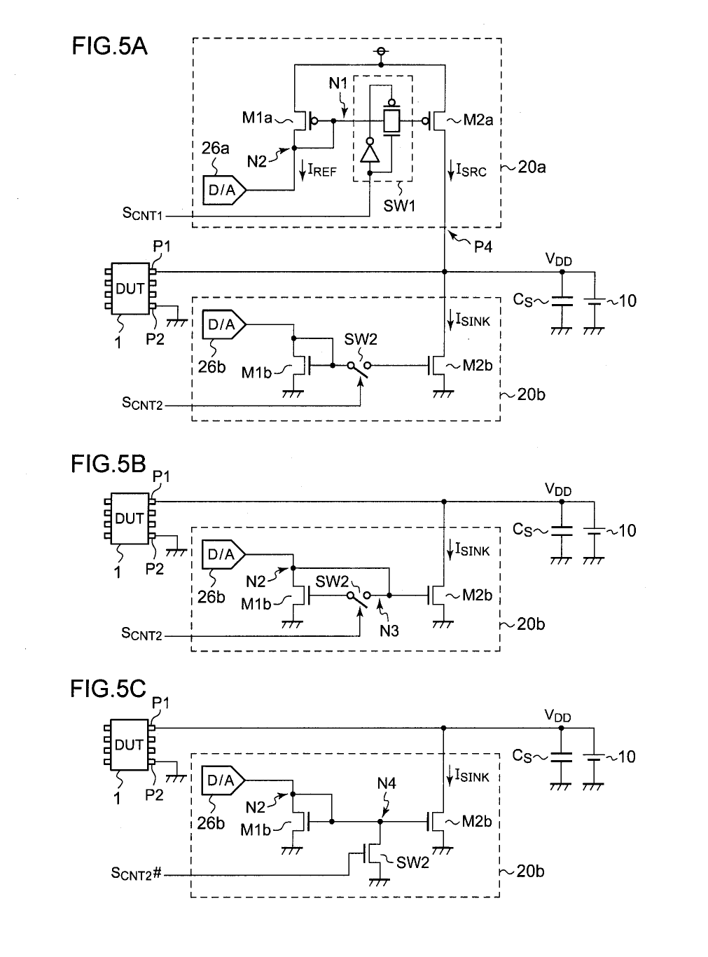

In a case in which such a problem becomes conspicuous, the following technique may be employed in order to solve such a problem. FIGS. 5A through 5C are circuit diagrams each showing a different example configuration of the power supply compensation circuit 20.

A source compensation circuit 20a shown in FIG. 5A includes a current D/A converter 26a, a first transistor M1a, a second transistor M2a, and a source switch SW1.

The current D/A converter 26a is configured to generate a reference current I_{REF} that corresponds to a digital setting signal D_{SET}. The first transistor M1a and the second transistor M2a form a current mirror circuit, which is configured to generate a sink pulse current I_{SINK} obtained by multiplying the reference current I_{REF} by a predetermined coefficient (mirror ratio K).

Specifically, the first transistor M1a is configured as a P-channel MOSFET, and is arranged on a path of the reference current I_{REF}. The second transistor M2 is also configured as a P-channel MOSFET, and is arranged such that the gate thereof is connected to the gate and the drain of the first transistor M1a.

In FIG. 5A, the source switch SW1 is arranged between the gate of the first transistor M1a and the gate of the second transistor M2a. For example, the source switch SW1 is configured as a transfer gate as shown in FIG. 5A. Alternatively, the source switch SW1 may be configured employing only N-channel MOSFETs or only P-channel MOSFETs. The on/off state of the source switch SW1 is switched according to a control signal S_{CNT1}.

In FIG. 5A, the drain N2 of the first transistor M1a is connected to the terminal N1 of the source switch SW1 on the side of the gate of the first transistor M1a.

During the period in which the control signal S_{CNT1} is high level, the source switch SW1 is turned on. In this state, the source pulse current I_{SRC} that is proportional to the reference current I_{REF} is discharged from the output terminal P4 of the source compensation circuit 20a. During a period in which the control signal S_{CNT1} is low level, the source switch SW1 is turned off. In this state, the current mirror circuit does not operate, which sets the source pulse current I_{SRC} to zero.

As described above, the source compensation circuit 20a shown in FIG. 5A is capable of generating the source pulse current I_{SRC} that is switched on and off according to the control signal S_{CNT1}.

With such a source compensation circuit 20a shown in FIG. 5A, such an arrangement provides improvement in the stability of the amplitude of the source pulse current I_{SRC}. Furthermore, the target to be driven by the driver DR is not a switch via which a large amount of current would flow. Instead, the target to be driven by the driver DR is a switch arranged at the gate of the current mirror circuit. Thus, such an arrangement enables high-speed switching.

Furthermore, with the source compensation circuit 20a shown in FIG. 5A, the reference current I_{REF} continuously flows through the first transistor M1a even if the source switch SW1 is set to the off state, thereby maintaining the bias state of the first transistor M1a. Thus, such an arrangement has an advantage of a high response speed in the switching of the source compensation circuit 20a with respect to the switching of the source switch SW1.

The sink compensation circuit 20b can be configured by reversing the conductivity type of each transistor, and by inverting the configuration of the source compensation circuit 20a. FIG. 5A shows an example configuration of the sink compensation circuit 20b. The sink compensation circuit 20b includes a current D/A converter 26b, transistors M1b and M2b which are each configured as an N-channel MOSFET, and a sink switch SW2. The sink compensation circuit 20b has the advantages as those of the source compensation circuit 20a.

FIGS. 5B and 5C each show only a configuration of the sink compensation circuit 20b, and the source compensation circuit 20a is not shown in these drawings.

FIG. 5B shows an arrangement in which the sink switch SW2 is arranged at a position that differs from that shown in FIG. 5A. In FIG. 5B, the drain N2 of the first transistor M1b is connected to the terminal N3 of the sink switch SW2 on the side of the gate of the second transistor M2b.

Such an arrangement is also capable of generating a sink pulse current I_{SINK} having a stabilized amplitude and that can be switched at a high speed, as with the configuration shown in FIG. 5A.

Furthermore, with such an arrangement shown in FIG. 5B, when the sink switch SW2 is turned off, the reference current I_{REF} is cut off. Thus, such an arrangement has an advantage of a reduction in the current consumption of the circuit.

In FIG. 5C, the sink switch SW2 is arranged between a gate N4, obtained by connecting the gates of the first transistor M1b and the second transistor M2b so as to form a common gate terminal, and a fixed voltage terminal such as a ground terminal. When the sink switch SW2 is turned on, i.e., during a period in which a control signal S_{CNT2}# (“#” represents logical inversion) is high level, the gate voltage of each of the first transistor M1 and the second transistor M2 is set to the ground voltage. In this state, the current mirror circuit is turned off, and accordingly, the sink pulse current I_{SINK} is cut off. When the sink switch SW2 is turned off, i.e., during a period in which the control signal S_{CNT2}# is low level, the current mirror circuit is turned on. In this state, the sink pulse current I_{SINK} flows.

Such an arrangement shown in FIG. 5C is capable of generating a sink pulse current I_{SINK} having a stabilized amplitude and that can be switched at a high speed, as with the aforementioned arrangements shown in FIGS. 5A and 5B. It is needless to say that such modifications shown in FIGS. 5B and 5C can be applied to the source compensation circuit 20a.

Also, such an arrangement shown in FIG. 5C may be combined with the arrangement shown in FIG. 5A or the arrangement shown in FIG. 5B.

The current that flows through the internal components that form the DUT 1, i.e., the operating current I_{OP} changes due to process variations. That is to say, when a given test pattern is supplied to the DUT 1, there are irregularities in the waveform of the operating current of the DUT 1 due to process variations. In order to solve such a problem, before the test step for the DUT 1, a calibration step may be performed in which the amplitude of the compensation pulse current is adjusted. Such an arrangement is capable of maintaining the power supply environment at a constant level even if there are irregularities in the operating current I_{OP} of the DUT 1 due to process variations. Such calibration can be performed by adjusting the digital setting value D_{SET} for the current D/A converters 26a and 26b.

The above is an example configuration of the power supply compensation circuit 20.

With such a test operation for a semiconductor device, there are two kinds of test operations, i.e., a test operation for a device under test which has been packaged after the assembling process (final test), and a test operation for a device under test in the form of a chip on a wafer before the assembling process (probe test). With such an arrangement, the probe test is performed in a difficult power supply environment, as compared with that in which the final test is performed. Thus, the compensation technique for the power supply voltage is critical not only in the final test, but also in the probe test.

With such an arrangement, the probe test is performed in a state in which probes are pressed in contact with pads arranged on a device under test in the form of a chip on a wafer. Accordingly, the correction using a compensation current is subject to effects of the resistance component and the inductance component of each probe itself, or the contact resistance that occurs between each probe and the chip. This leads to difficulty in maintaining the power supply voltage at a constant level.

Accordingly, in order to compensate for the power supply with higher accuracy in the probe test, at least a part of the power supply compensation circuit 20 shown as an example in FIGS. 4A and 4B and FIG. 5A through 5C, is formed on the wafer.

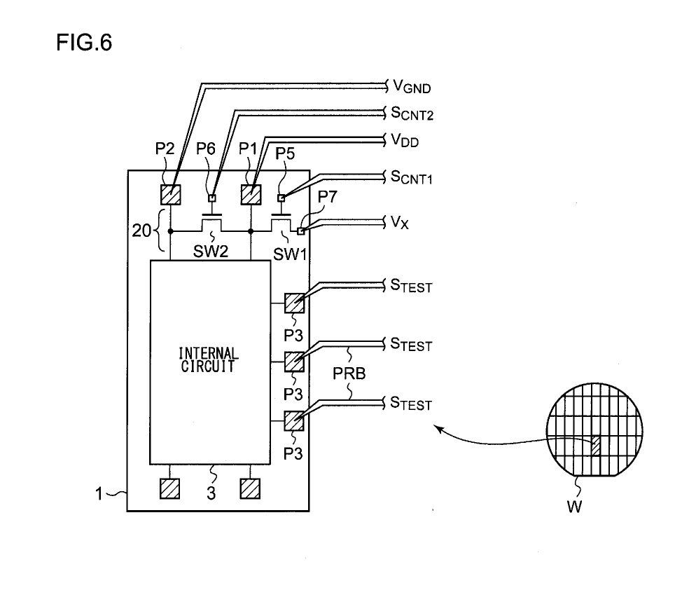

FIG. 6 is a first example in which a part of the power supply compensation circuit 20 shown in FIG. 4A is formed on the wafer. In FIG. 6, a part of the power supply compensation circuit 20 is formed within a DUT 1 chip. The DUT 1 chip includes pads (which will also be referred to as the “function pads” hereafter) that respectively correspond to a power supply terminal P1, a ground terminal P2, I/O terminals P3, and an internal circuit 3, which are necessary for the functions of the DUT 1 chip itself. In addition, a source switch SW1, a sink switch SW2, and compensation pads P5 through P7, are formed on the DUT 1 chip.

The compensation pads P5 and P6 are respectively connected to the gates of the source switch SW1 and the sink switch SW2, and are respectively configured to apply the control signal S_{CNT1} and S_{CNT2}. The compensation pad P7 is connected to one terminal of the source switch SW1, and is configured to apply a voltage Vx to the source switch SW1.

Various kinds of signals are applied via probes PRB to the function pads P1 through P3 and the compensation pads P5 through P7. In the DUT 1 in a packaged state, the function pads P1 through P3 are connected to external connection terminals such as leads or bumps. On the other hand, the compensation pads P5 through P7 are unnecessary for the functions of the DUT 1 itself. Accordingly, there is no need to connect such compensation pads to external connection terminals. Thus, preferably, the compensation pads P5 through P7 are each formed with a small size, which is small to the extent that each compensation pad can be contacted with a probe but cannot be connected to an external connection terminal when the DUT 1 is packaged.

With such a configuration, a part of the power supply compensation circuit 20 is formed on the wafer. Thus, at the time of the probe test, such an arrangement is capable of generating the compensation pulse currents I_{SRC} and I_{SINK} on the wafer, i.e., in the vicinity of the internal circuit 3 of the DUT 1. As a result, such an arrangement provides power supply compensation in a state in which the effects of the impedance of the probes are suppressed.

Furthermore, with such an arrangement in which a part of the power supply compensation circuit 20 is formed on the wafer, variations in the elements that form the power supply compensation circuit 20 correspond to variations in the elements that form the DUT 1. Accordingly, with variation in the operating current I_{OP} of the DUT 1 such that it becomes greater, the currents I_{SRC} and I_{SINK} that respectively flow through the source switch SW1 and the sink switch SW2 also change in the same direction of becoming greater. Thus, such an arrangement provides accurate current compensation.

Moreover, in a case in which a part of the power supply compensation circuit 20 formed within the chip is required only at the time of the probe test, by configuring the compensation pads P5 through P7 with a sufficiently small size, such an arrangement suppresses an increase in the chip size.

It should be noted that, in a case in which there is a sufficient margin in the chip size, the compensation pads P5 through P7 may be configured on the order of the same size as that of the ordinary function pads. Furthermore, such compensation pads P5 through P7 may be connected to corresponding external connection terminals. Such an arrangement also provides power supply compensation using the power supply compensation circuit 20 formed within the DUT 1 chip even in the test after packaging (final test).

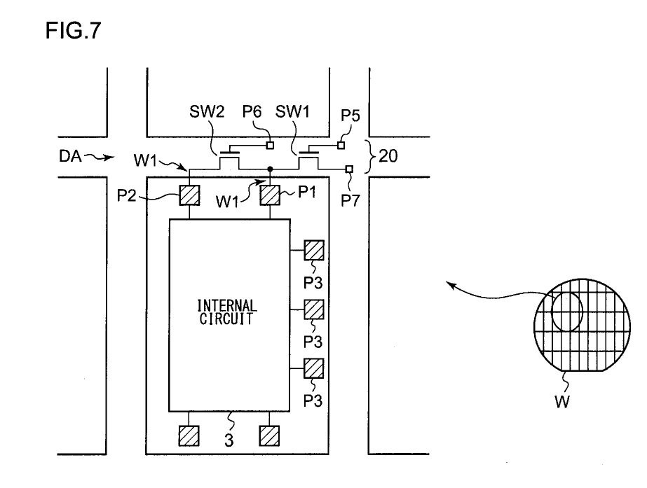

FIG. 7 is a diagram showing a second example in which a part of the power supply compensation circuit 20 shown in FIG. 4A is formed on the wafer W. There is a dicing area (scribe region) DA around the edge of the chip before the chip is diced from the wafer. FIG. 7 shows an arrangement in which a part of the power supply compensation circuit 20 (i.e., the source switch SW1, the sink switch SW2, and the compensation pads P5 through P7) is formed in the dicing area DA, which is the outer region of the DUT 1 chip.

Among the wiring lines connected to a part of the power supply compensation circuit 20 and the compensation pads P5 through P7, a wiring line W1 that straddles the boundary of the chip is preferably configured as an aluminum wiring line. In a case in which the wiring line W1 is arranged across the boundary of the chip, the cross-sectional surface of the wiring line W1 is exposed to air or moisture after the dicing. In some cases, this leads to deterioration in long-term reliability. In order to solve such a problem, such a wiring line is configured as a first layer aluminum wiring line instead of a copper wiring line, thereby suppressing deterioration in reliability.

In a case in which the power supply compensation circuit 20 formed on the wafer W is only required for a probe test, such a power supply compensation circuit 20 may be formed in the dicing area, thereby suppressing an increase in the chip area.

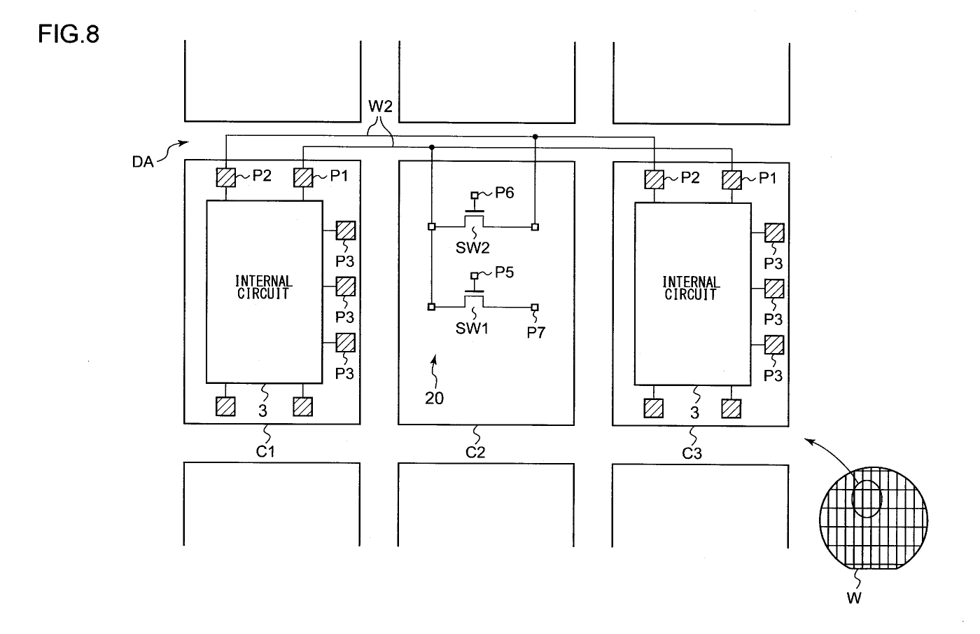

FIG. 8 is a diagram showing a third example in which a part of the power supply compensation circuit 20 shown in FIG. 4A is formed on the wafer W. In FIG. 8, such a part of the power supply compensation circuit 20 (SW1 and SW2) and the compensation pads P5 through P7, which are to be formed on the wafer, are formed on a chip C2 that is separate from the chip C1 on which the DUT 1 is formed.

The function pads P1 and P2 formed on the chip C1 are connected to the power supply compensation circuit 20 via a wiring line W2 formed in the dicing area DA.

Preferably, at least a part of the power supply compensation circuit 20 (SW1 and SW2) and the compensation pads P5 through P7, which are formed on a given chip C2 of the wafer, may be shared by multiple chips adjacent to the chip C2. FIG. 8 shows an arrangement in which the power supply compensation circuit formed in the chip C2 is shared by the chips C1 and C3. Also, such a power supply compensation circuit chip C2 may be shared by different adjacent chips, in addition to the chips C1 and C3. For example, such a single power supply compensation circuit chip C2 may be shared by eight adjacent chips, i.e., by the adjacent chips along the four sides and at the four corners. Also, such a power supply compensation circuit chip C2 may be shared by different chips, in addition to such eight adjacent chips.

FIG. 8 shows an arrangement in which the power supply compensation circuit formed on the chip C2 is shared by the chips C1 and C3, and the compensation current is supplied to each of the chips C1 and C3. However, the present invention is not restricted to such an arrangement. Also, control switches may be respectively arranged on paths via which compensation current is supplied from the power supply compensation circuit formed on the chip C2 to the chips C1 and C3. Such an arrangement may be configured to control the respective control switches so as to select and switch the chip which is to receive the supply of the compensation current. With such an arrangement, the compensation pads each configured to supply a control signal that is used to switch the state of the control switch may be arranged in the chip C2 area.

In a case in which such power supply compensation circuit chips C2 are arranged on a wafer, the number of product chips produced from a wafer is reduced due to the area of such power supply compensation circuit chips C2. With such an arrangement in which the power supply compensation circuit chip C2 is shared by multiple chips, such an arrangement suppresses a reduction in the number of product chips. In the probe test, in some cases, multiple chips are measured at the same time.

With such an arrangement as shown in FIG. 8 in which the power supply compensation circuit chip C2 is provided, wiring lines that connect the power supply compensation circuit chip C2 and the chips C1 and C3, each of which is a device under test, may be omitted. Instead, the power supply compensation circuit chip C2 and the chips C1 and C3 may be connected via probes. Such an arrangement has a problem in that the power supply compensation is subject to the effects of the probes. However, such an arrangement also has an advantage in that variation that occurs in the power supply compensation circuit 20 is similar to that in the DUT 1.

Description has been made regarding the present invention with reference to the embodiments. However, the above-described embodiments show only the mechanisms and applications of the present invention for exemplary purposes only, and are by no means intended to be interpreted restrictively. Rather, various modifications and various changes in the layout can be made without departing from the spirit and scope of the present invention defined in appended claims.

Description has been made in FIG. 6 through FIG. 8 regarding an arrangement in which the power supply compensation circuit 20 shown in FIG. 4A is employed. Also, a part of or the entire configuration of any of the power supply compensation circuits 20 shown in FIG. 4B and FIGS. 5A through 5C may be formed on a wafer.

For example, in a case in which the power supply compensation circuit 20 shown in FIG. 4B is employed, the source switch SW1 and the sink switch SW2 may be formed on the wafer, and the source current source 24a and the sink current source 24b may be formed external to the wafer. Conversely, the source current source 24a and the sink current source 24 may be formed on the wafer, and the source switch SW1 and the sink switch SW2 may be formed external to the wafer. Alternatively, all the components may be formed on the wafer.

In the case of any of the power supply compensation circuits 20 shown in FIGS. 5A through 5C, the first transistor M1, the second transistor M2, the source switch SW1, and the sink switch SW2 may be formed on a wafer. With such an arrangement, variations in the first transistor M1 and the second transistor M2 are similar to those in the DUT 1. Thus, such an arrangement provides improved accuracy of the power supply compensation. Furthermore, the current D/A converters 26a and 26b may also be formed on the wafer.

By forming a part of or the entire configuration of the power supply compensation circuit 20 on the wafer, such an arrangement is capable of providing accurate power supply compensation in the probe test even if the power supply compensation circuit 20 is configured in a different manner.

Description has been made in the embodiment regarding an arrangement configured to provide an ideal power supply environment having no fluctuation in the power supply voltage, i.e., having zero output impedance, using the compensation current I_{CMP}. However, the present invention is not restricted to such an arrangement. That is to say, the waveform of the compensation current I_{CMP} may be calculated so as to provided an intentional change in the power supply voltage, and the control pattern S_{PTN}_{_{—}}_{CMP} may be determined so as to provide such a compensation current waveform. Such an arrangement is capable of emulating a power supply environment as desired according to the control pattern S_{PTN}_{_{—}}_{CMP}.

Description has been made in the embodiment regarding an arrangement in which the power supply compensation circuit 20 includes the source compensation circuit 20a and the sink compensation circuit 20b. However, the present invention is not restricted to such an arrangement. Also, the power supply compensation circuit 20 may be configured including only one of either the source compensation circuit 20a or the sink compensation circuit 20b.

In a case in which the power supply compensation circuit 20 includes only the source compensation circuit 20a, such an arrangement may instruct the source compensation circuit 20a to generate a constant current IDC. With such an arrangement, when a shortfall occurs in the power supply current I_{DD} with respect to the operating current I_{OP}, the current I_{SRC} generated by the source compensation circuit 20a may be increased relative to the constant current IDC. Conversely, when the power supply current I_{DD} is excessive with respect to the operating current I_{OP}, the current I_{SRC} generated by the source compensation circuit 20a may be reduced relative to the constant current IDC.

In a case in which the power supply compensation circuit 20 includes only the sink compensation circuit 20b, such an arrangement may instruct the sink compensation circuit 20b to generate a constant current IDC. With such an arrangement, when a shortfall occurs in the power supply current I_{DD} with respect to the operating current I_{OP}, the current I_{SINK} generated by the sink compensation circuit 20b may be reduced relative to the constant current IDC. Conversely, when the power supply current I_{DD} is excessive with respect to the operating current I_{OP}, the current I_{SINK} generated by the sink compensation circuit 20b may be increased relative to the constant current IDC.

Such an arrangement has a disadvantage of increased current consumption in the overall operation of the test apparatus by the constant current IDC thus generated.

However, such an arrangement has an advantage in that it requires only a single switch to generate the compensation currents I_{SRC} and I_{SINK}.

While the preferred embodiments of the present invention have been described using specific terms, such description is for illustrative purposes only, and it is to be understood that changes and variations may be made without departing from the spirit or scope of the appended claims.

What is claimed is:

1. A test apparatus configured to test a device under test formed on a wafer, the test apparatus comprising:
a main power supply configured to supply electric power to a power supply terminal of the device under test;
a power supply compensation circuit comprising a switch element configured to be controlled according to a control signal, and configured to generate a compensation pulse current when the switch element is turned on, and to inject the compensation pulse current thus generated into the power supply terminal via a path that differs from that of the main power supply, or to draw the compensation pulse current from the power supply current that flows from the main power supply to the device under test via a path that differs from that of the device under test;
a plurality of drivers, one of which is assigned to the switch element, and of which at least one other is assigned to at least one of the input/output terminals of the device under test;
a plurality of interface circuits provided to the respective drivers, each configured to shape an input pattern signal, and to output the pattern signal thus shaped to the corresponding driver; and
a pattern generator configured to output a test pattern which specifies a test signal to be output from the driver assigned to the input/output terminal of the device under test to the interface circuit that corresponds to the driver, and to output, to the interface circuit that corresponds to the driver assigned to the switch element, a control pattern determined according to the test pattern,
wherein at least one part of the power supply compensation circuit, including the switch element, is formed on the wafer,
and wherein a compensation pad is arranged via which a signal is applied to the at least one part of the power supply compensation circuit formed on the wafer.

2. A test apparatus according to claim 1, wherein at least one part of the power supply compensation circuit formed on the wafer and the compensation pad are formed within a chip in which the device under test is configured.

3. A test apparatus according to claim 2, wherein the compensation pad is formed with a size which allows a probe to be in contact with the compensation pad, and which is smaller than the size of a function pad which is connected to an external connection terminal when the device under test is packaged.

4. A test apparatus according to claim 2, wherein the compensation pad is connected to an external connection terminal when the device under test is packaged.

5. A test apparatus according to claim 1, wherein at least one part of the power supply compensation circuit formed on the wafer and the compensation pad are formed in a dicing area external to the chip in which the device under test is formed.

6. A test apparatus according to claim 1, wherein the at least one part of the power supply compensation circuit formed on the wafer and the compensation pad are formed in a power compensation circuit chip that is separate from the chip in which the device under test is formed.

7. A test apparatus according to claim 6, wherein the at least one part of the power supply compensation circuit formed on the wafer and the compensation pad are shared by a plurality of devices under test.

8. A test apparatus according to claim 5, wherein, of wiring lines respectively connected to the at least one part of the power supply compensation circuit formed on the wafer and the compensation pad, a wiring line that straddles a boundary of the chip is formed as an aluminum wiring line.

9. A test apparatus according to claim 6, wherein, of wiring lines respectively connected to the at least one part of the power supply compensation circuit formed on the wafer and the compensation pad, a wiring line that straddles a boundary of the chip is formed as an aluminum wiring line.

10. A test apparatus according to claim 7, wherein, of wiring lines respectively connected to the at least one part of the power supply compensation circuit formed on the wafer and the compensation pad, a wiring line that straddles a boundary of the chip is formed as an aluminum wiring line.
